(19) United States
(12) Patent Application Publication
(10) Pub. No.: US 2005/0212090 A1
(43) Pub. Date: Sep. 29, 2005

(54) Integrated circuit

(76) Inventors: Ulrich Friedrich, Ellhofen (DE); Dirk Ziebertz, Eberstadt (DE)

Correspondence Address: BIRCH STEWART KOLASCH & BIRCH, PO BOX 747, FALLS CHURCH, VA, 22040-0747, US

(21) Appl. No.: 11/088,886

(22) Filed: Mar. 24, 2005

(30) Foreign Application Priority Data
Mar. 25, 2004 (DE) 10 2004 014644.6

(51) Int. Cl. H01L 23/544

(52) U.S. Cl. 257/620

(57) ABSTRACT

An integrated circuit includes a cuttable circuit structure, which in a cut state prevents access to at least one circuit element of the integrated circuit. Whereby, the circuit structure is positioned so that it is cut during dicing of the integrated circuit from a wafer.

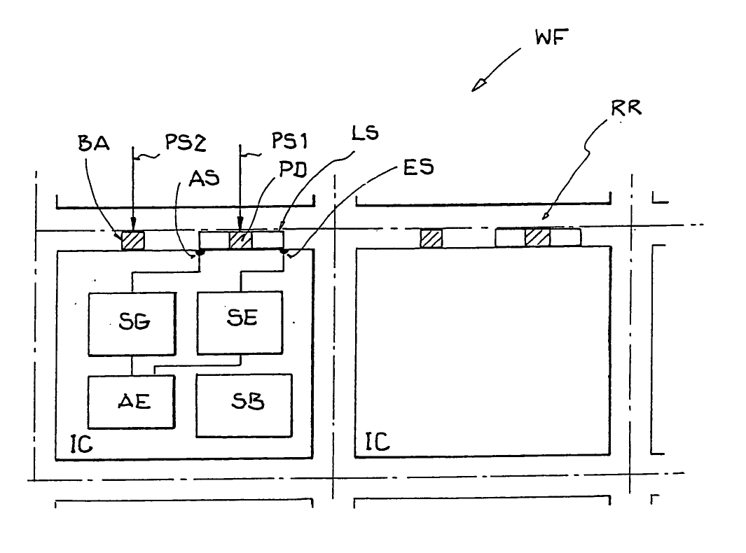

This nonprovisional application claims priority under 35 U.S.C. § 119(a) on German Patent Application No. DE 102004014644.6, which was filed in Germany on Mar. 25, 2004, and which is herein incorporated by reference.

### BACKGROUND OF THE INVENTION

1. Field of the Invention

The present invention relates to an integrated circuit with a cuttable circuit structure, which in a cut state prevents access to at least one circuit element of the integrated circuit.

2. Description of the Background Art

Integrated circuits can contain as circuit elements one or more data memories, which store data, for example, in binary form. The data memory can be, for example, an ROM, EPROM, or EEPROM. Typically, during the manufacturing process certain data are written or programmed hereby into a data memory or circuit element of the integrated circuit, which should not be changed after the manufacture of the circuit or during its intended use. In certain cases, even reading out of these data is undesirable.

Various technologies and methods are known to prevent such inadvertent read and/or write access to a specific circuit element or to the data contained therein.

A widely used option is access protection through use of a password. If, however, an attempted, unsuccessful access cannot be stored within the integrated circuit, the password can be changed until access is finally possible. If an access release after input of a correct password is stored as a bit value in a dynamic memory element, for example, a flip-flop, it is possible in addition to sweep the memory content of the memory element by selectively changing a supply voltage of the integrated circuit and in this way to enable unauthorized access.

If EEPROMS are used as the data memory, program access is usually prevented by lock bits. An allocated memory cell of the EEPROM is programmed for this purpose. If access to the integrated circuit occurs, first the value of this cell is read out and evaluated. If the value is, for example, “1,” access is blocked or prevented. Access release is hereby again typically stored as a bit value in a dynamic memory element, as a result of which, as already described above, unauthorized access is possible by selectively changing the supply voltage of the integrated circuit.

Particularly during use of so-called chip cards, for example, in bankcards, one-sided and two-sided authentication mechanisms are used, which are based on so-called crypto algorithms. This requires, however, that appropriate circuit elements, which support such crypto algorithms, must be present on the integrated circuit. As a result, the required chip area and the necessary power requirement increase. Here as well, there is again the risk of unauthorized access through a change in the supply voltage, if the result of the authentication process is stored in a dynamic memory element.

In ISO WD 18000-6 WD Mode 3 of Feb. 1, 2003, a method is described in which the data are saved encrypted in the integrated circuit. The decryption of these data is possible only with the use of external decryption information, which is filed, for example, in a computer, which can be accessed securely via a network.

Another option for access protection is the use of fuse structures for storing of only one-time writable memory areas. In this regard, each bit of a datum to be stored is allocated a fuse in the structure, which as a function of the significance of the bit that is to be programmed is destroyed, e.g., cut, or remains intact during programming. A requirement for this, however, is a semiconductor process, which can provide such fuses. Furthermore, the space requirement also increases considerably with the increase in the size of the data to be stored.

In addition to the storing of bit values with the use of fuse structures, access can also be controlled with use of a fuse structure or a circuit structure, whereby access is prevented in a cut or destroyed state of the fuse or the circuit. Typically, the cutting occurs in a manufacture step especially designated for this at the wafer level.

### SUMMARY OF THE INVENTION

It is therefore an object of the present invention to provide an integrated circuit having a cuttable circuit structure, which in a cut state can prevent access to at least one circuit element of the integrated circuit, and of a wafer, which enable safe and secure access control and which are simple to realize and if possible require no additional manufacturing steps at the wafer level.

In an example embodiment of the present invention, the circuit structure is positioned so that it is cut when the integrated circuit is diced from a wafer. Thereby, in a dicing step occurring at the wafer level, at the same time access to one or more circuit elements is also blocked. A separate manufacture step, in which the circuit structure or fuse is destroyed or cut, can therefore be omitted. Through the cutting, read and/or write access can be prevented. It is also possible to block certain operations or commands, such as, for example, certain test routines, which may run only at the wafer level. Due to the destruction of the circuit structure, after the dicing, it is virtually impossible to bond the remaining circuit elements afterwards to enable an unauthorized access, for example, by applying potentials.

The circuit structure can also be positioned in a scribing frame of the wafer. With this type of positioning of the circuit structure, no additional room is required in a functional area with a high integration density of the integrated circuit. This enables a cost-effective and simple manufacture.

Further, at least one circuit element can include a memory, particularly an EEPROM. In this manner, the EEPROM can be protected from unauthorized access in a simple and effective manner.

The cuttable circuit structure can connect an output circuit node with an input circuit node of the integrated circuit. In this manner, rather complex dynamic security mechanisms can be implemented, which prevent unauthorized access through static application of a potential at input circuit nodes. The input circuit node can be provided with a pull-up resistor or a pull-down resistor and/or the output circuit node can be designed as an open drain connection. As a result, the input circuit node is at a defined potential after dicing. A state of the input can be entered or sampled once, for example, during an initialization of the circuit, or can be repeatedly entered or sampled. Repeated sampling can occur, for example, with a clock frequency that can be derived from an internal oscillator clock, or run by external clock signals. If the input circuit node is designed as an open drain connection, the possibility exists at the wafer level to contact additional external testing devices to the circuit nodes.

The integrated circuit can also include a signal generating unit, which is designed to generate an output signal at an output circuit node, a signal detection unit, which is designed to detect an input signal at an input circuit node, and an evaluation unit, which is coupled with the signal generating unit and the signal detection unit and which is designed to compare the output signal with the input signal and generates an access release signal, whereby the access release signal is set if the output signal matches the input signal. A match can also exist if the input signal is inverted in comparison with the output signal. The dynamic detection of the states applied to the input circuit node prevents unauthorized access, if any static signal was applied to the input circuit node by manipulation. The signal generating unit can generate the output signal as a conjunction with messages that can be received through the integrated circuit. Alternatively or in combination, the signal generating unit can generate the output signal in connection with a state of memory cells, which can be located in the integrated circuit. A prediction or emulation of the signal effecting release, which can be applied to the input circuit node, is thereby made more difficult as a result.

The cuttable circuit structure can have at least one pad or contact area, which is designed for bonding with a programmable device, whereby the pad is destroyed during dicing of the integrated circuit from the wafer. Thus, a simple electrical bonding of the integrated circuit at the wafer level is achieved, because the pad provides a sufficient contact area. After dicing, bonding is practically ruled out.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein the single FIGURE shows a schematic illustration of a top view of a wafer having integrated circuits arranged thereon.

### DETAILED DESCRIPTION

The single FIGURE schematically shows a top plan view of a portion of a wafer WF, on which integrated circuits IC are arranged. In addition, a programming device (not shown) is provided for initializing and programming the integrated circuits IC at the wafer level. Of course, several similar integrated circuits IC are arranged on the wafer WF, whereby, however, for reasons of a simpler presentation only two integrated circuits IC are shown.

The integrated circuit IC can be a transponder, for example, a radio-frequency-identification (RFID) circuit. The integrated circuit IC can include a circuit elements, such as a memory area SB, which can be designed as an EEPROM, a cuttable circuit structure LS, which can connect an output circuit node AS with an input circuit node ES, a signal generating unit SG for generating an output signal at the output circuit node AS, a signal detection unit SE for detecting an input signal at the input circuit node ES, and an evaluation unit AE, coupled to the signal generating unit SG and the signal detection unit SE, for comparing the output signal with the input signal and for producing an access release signal.

The input circuit node ES is wired to a pull-down resistor (not shown) and the output circuit node AS is constructed as an open drain connection. The circuit nodes AS and ES in a finished assembled integrated circuit IC are not constructed as connections that can be contacted by a user.

The cuttable circuit structure LS, which can be provided approximately halfway between the output circuit node AS and the input circuit node ES, has a pad PD that is used to enable contact with the program device. For contacting with the program device, a reference potential connection BA can be provided, which can also be designed as a pad.

The programming device can be used, for example, to initialize or program the memory area SB. This requires that an appropriate programming access in the transponder is released. When the programming access is released or is possible, data that is to be stored in the memory area SB by the programming device are programmed in a conventional manner, not depicted, in the memory area SB.

An inactive output circuit node AS exists in a high-impedance state, because it is constructed as an open drain connection. Because of the pull-down resistor at the input circuit node ES, the input is pulled to the reference potential, i.e., ground. This corresponds to the state of circuit structure LS being cut. Thus, programming and/or reading out of the memory area SB is blocked. It can be checked in this way even at the wafer level whether the integrated circuit IC in fact blocks access during cutting of the circuit structure LS.

For release, two test tips PS1 and PS2 of the programming device are contacted to the pad PD of the circuit structure LS or the reference potential connection BA. The first test tip PS1 connects a first connection of the programming device with the pad PD of the circuit structure LS and the second test tip PS2 connects the reference potential connection BA of the integrated circuit IC with a reference potential of a second connection of the programming device PV. The first connection can be wired internally with a pull-up resistor, which is dimensioned so that with an inactive output circuit node AS the potential of the input circuit node ES pulls to a supply voltage level; i.e., it has a lower impedance than the pull-down resistor of the input circuit node ES. Only when the output circuit node AS is active, does the output transistor of the node (not shown) again pull the potential of the input circuit node ES to ground.

In the simplest case, a release can now occur if the potential of the input circuit node ES is statically at the supply voltage level. Improved protection from unauthorized access, however, can be achieved by a dynamic generation of the signal applied to the input circuit node ES. For this purpose, the signal generating unit SG generates a dynamic signal at the output circuit node AS, which with an intact circuit structure LS and the programming device that is contacted thereto causes an appropriate signal at the input circuit node AS and is detected by the signal detection unit SE. The evaluation unit AE compares the two signals and produces a release access signal, i.e., enables access if the output signal matches the input signal.

The output signal can be generated, for example, from messages received by the integrated circuit IC or the transponder. Alternatively or in addition, the signal generating unit SG can generate the output signal as a function of the state of the memory cells SB, which are located in the integrated circuit IC.

Another possibility is access control at several, for example, two levels. In this case, the contents of a memory cell, provided especially for this purpose (not shown) determines an access level, whereby the content of the memory cell according to the wafer level can still be changed once by the user. At the wafer level, with an intact circuit structure LS, the content of this memory cell is set, for example, to the state “1” or programmed. After cutting of the circuit structure LS, for example, a read-only access but not write access is then possible. Through selective radiation by the user with UV light, the content of the memory cell in the case of an EEPROM can now only be changed from state “1” to state “0.” Another change to the state “1” is no longer possible because of the cut circuit structure LS. If the state of the memory cell is “0,” neither writing nor reading is possible.

The integrated circuits IC of the wafer can be diced, which can occur through a scribing or sawing step along a scribing frame RR of the wafer WF. Through this dicing step, the circuit structure LS including the pad PD and the reference connection BA is destroyed. The potential of the input circuit node ES is now pulled statically to ground in the operating mode by the pull-down resistor, as a result of which access, as described above, is totally or partially blocked.

Because the pad PD and the reference connection BA are also removed by the dicing step, the possibility of later contacting (connecting) to access the memory area without authorization is greatly impeded, because the connection necessary for release is now possible only at the remaining free circuit ends of the circuit structure LS, which have a very small cross-section and can therefore virtually not be found.

The described exemplary embodiment makes possible a simple and secure access control, which is simple to realize and does not require additional manufacturing steps at the wafer level.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. An integrated circuit comprising:
at least one circuit element being provided on the integrated circuit; and
a cuttable circuit structure, which in a cut state prevents access to the at least one circuit element,
wherein the cuttable circuit structure is positioned so that it is cut during dicing of the integrated circuit from a wafer.

2. The integrated circuit according to claim 1, wherein the circuit structure is provided in a scoring frame of the wafer.

3. The integrated circuit according to claim 1, wherein the at least one circuit element comprises a memory.

4. The integrated circuit according to claim 1, wherein the cuttable circuit structure connects an output circuit node with an input circuit node of the integrated circuit.

5. The integrated circuit according to claim 4, wherein the input circuit node is provided with a pull-up resistor or a pull-down resistor and/or the output circuit node is constructed as an open drain connection.

6. The integrated circuit according to claim 4, wherein a signal generating unit generates an output signal at the output circuit node, a signal detection unit detects an input signal at the input circuit node, and an evaluation unit, which is coupled with the signal generating unit and the signal detection unit, compares the output signal with the input signal and generates an access release signal, the access release signal being set if the output signal matches the input signal.

7. The integrated circuit according to claim 6, wherein the signal generating unit generates the output signal on the basis of a message received by the integrated circuit.

8. The integrated circuit according to claim 6, wherein the signal generating unit generates the output signal on the basis of a state of a memory cell, which is provided in the integrated circuit.

9. The integrated circuit according to claim 1, wherein the cuttable circuit structure includes at least one pad, which enables contact with a programming device, and wherein the pad is destroyed during dicing of the integrated circuit from the wafer.

10. The integrated circuit according to claim 1, wherein a plurality of the integrated circuits are provided on the wafer.

11. The integrated circuit according to claim 1, wherein the integrated circuit is an RFID circuit.

12. The integrated circuit according to claim 3, wherein the memory is an EEPROM.

13. A method of selectively controlling access to an integrated circuit, the method comprising the steps of:
providing the integrated circuit on a wafer; and
providing a cuttable circuit structure, the cuttable circuit structure facilitating access to a memory area of the integrated circuit,
wherein, upon dicing the integrated circuit from the wafer, access to the memory area through the cuttable circuit structure is prevented.

14. The method according to claim 13, wherein a programmable devices accesses the memory area of the integrated circuit via a contact pad that is provided on the cuttable circuit structure.

15. The method according to claim 14, wherein the cuttable circuit structure is electrically connected with an input node and an output node, the input node being connected with a signal generating unit and the output node being connected with a signal detection unit.

16. The method according to claim 13, wherein the cuttable circuit structure is disengaged from the integrated circuit upon dicing of the wafer, thereby preventing access to the memory area of the integrated circuit.
